(19) United States
(12) Patent Application Publication
(10) Pub. No.: US 2008/0095953 A1
(43) Pub. Date: Apr. 24, 2008

(54) APPARATUS FOR DEPOSITING THIN FILM AND METHOD OF DEPOSITING THE SAME

(75) Inventors: Heok-Jae LEE, Gyeonggi-do (KR); Jung-Hun CHO, Gyeonggi-do (KR); Se-Hwi CHO, Seoul (KR); Yun-Sik YANG, Gyeonggi-do (KR); Yong-Gyu LIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/923,395

(22) Filed: Oct. 24, 2007

(30) Foreign Application Priority Data
Oct. 24, 2006 (KR) 2006-0103673
Jun. 13, 2007 (KR) 2007-0057996

(51) Int. Cl. C23C 16/00; H05H 1/24

(52) U.S. Cl. 427/569; 118/723 E

(57) ABSTRACT

Provided are an apparatus for depositing a thin film using plasma which can prevent impurities from being formed by inhibiting plasma from being diffused into a nozzle pipe and sustained in the nozzle pipe and improve thickness uniformity of the deposited thin film and a method of depositing the same. The apparatus for depositing a thin film includes a chamber having a substrate holder and an inner space defined by an inner wall; and a nozzle pipe comprising a first end fixed to the inner wall of the chamber; a second end extending into the inner space of the chamber; a flow path penetrating the nozzle pipe from the first end to the second end; and at least one slit which is disposed at the second end and opens the flow path into the inner space of the chamber.

### CROSS-REFERENCE TO RELATED PATENT APPLICATION

This application claims priority under 35 USC §119 to Korean Patent Application Nos. 10-2006-0103673, filed on Oct. 24, 2006, and 10-2007-0057996, filed on Jun. 13, 2007, in the Korean Intellectual Property Office, the disclosures of which are incorporated herein in their entirety by reference.

### BACKGROUND

1. Technical Field

The present invention relates to an apparatus for manufacturing a semiconductor and a method of manufacturing a semiconductor, and more particularly, to an apparatus for depositing a thin film on a substrate using plasma and a method of depositing the thin film.

2. Description of the Related Art

Plasma chemical vapor depositions (PECVDs) are used to obtain excellent deposition properties of a thin film including high deposition speed at low pressure and/or low temperature, as well as excellent step coverage, adherence and electrical properties. Since process gases can be dissociated to become radicals, ionic species, excited atoms and molecules in a plasma state, high deposition speed and excellent properties of thin films can be obtained using PECVDs even at a lower temperature compared to using conventional chemical vapor depositions.

Recently, high-density plasma chemical vapor depositions using a high-density plasma (HDP) source have been used to further improve the effective properties of the plasma. The high-density plasma source inductively couples RF or electromagnetic energy to the plasma using a coil installed outside of a chamber while simultaneously capacitively coupling electrical energy to the plasma, and thus high-density plasma can be generated in the chamber. The generated high-density plasma provides high-density ionic species having low energy to the surface of a substrate, and thus a deposition process of a thin film and etch process by sputtering thereof can occur concurrently. Accordingly, a thin film in which gaps having a high aspect ratio are effectively filled without voids can be prepared using high-density plasma chemical vapor depositions.

However, in an apparatus for depositing a thin film using plasma discharge, impurities, such as by-products and particles from reactions, can be extensively deposited on the surface of an inner wall of the chamber which contacts the plasma, as well as the substrate. Particularly, the by-products can also be deposited on the opening of a nozzle pipe disposed in the chamber through which process gases are supplied, and these by-products may function as a secondary pollutant for a subsequent substrate in the chamber. Also, the by-products deposited on the opening of the nozzle pipe may alter the controlled flow amount of the process gas provided through the nozzle pipe.

Typically, cleaning of the chamber is performed to remove the by-products and/or impurities deposited on the inner wall of the chamber and/or the opening of the nozzle pipe. The cleaning of the chamber can be performed by injecting etch gas into the chamber and generating plasma. However, the impurities on the nozzle pipe are not sufficiently removed using only the plasma cleaning.

Further, processes to remove impurities formed on the nozzle pipe may be performed after the deposition apparatus is shut down, and thus the cleaning takes several times longer than operating the deposition apparatus. Accordingly, the process of cleaning the chamber, which reduces the time available for operating the deposition apparatus, may be an important factor in increasing the manufacturing costs.

In addition, it has been found by the inventors of the present invention, as a result of experiments depositing a thin film, that a uniform thin film cannot be easily obtained on a substrate due to high reactive radicals compared to conventional chemical vapor deposition and thickness uniformity of the deposited thin film cannot be easily obtained only by controlling process variations through pressure and flow amount regulation when a thin film is deposited using plasma. The present invention addresses these and other disadvantages of the conventional art.

### SUMMARY

The present invention provides an apparatus for depositing a thin film using plasma which can minimize the amount of impurities formed on a nozzle pipe through which process gas is supplied and provide a uniform thickness of the deposited thin film. The present invention also provides a method of depositing a thin film using plasma which can minimize the amount of impurities formed on a nozzle pipe through which process gas is supplied and provide a uniform thickness of the deposited thin film.

According to an aspect of the present invention, there is provided an apparatus for depositing a thin film using plasma including: a chamber having a substrate holder and an inner space defined by an inner wall; and a nozzle pipe including a first end fixed to the inner wall of the chamber; a second end extending into the inner space of the chamber; a flow path penetrating the nozzle pipe from the first end to the second end; and at least one slit which is disposed at the second end and opens the flow path into the inner space of the chamber.

Since the thin film thickness at the central region of a substrate is mainly determined by a long nozzle pipe during a thin film deposition, deposition speed at the central region of the substrate can be improved by improving directionality of reactant gases in accordance with some embodiments of the present invention.

### BRIEF DESCRIPTION OF THE DRAWINGS

The above and other features and advantages of the present invention will become more apparent by describing in detail exemplary embodiments thereof with reference to the attached drawings in which:

FIG. 1A shows a vertical cross-sectional view of an apparatus for depositing a thin film according to an embodiment of the present invention;

FIG. 1B shows a horizontal plan view of the apparatus for depositing a thin film shown in FIG. 1A taken along line IB-IB;

FIG. 2A shows a plan view illustrating a nozzle pipe including a slit according to an embodiment of the present invention;

FIG. 2B shows a side view of the nozzle pipe from the direction of an arrow A1 shown in FIG. 2A;

FIG. 2C shows a side view of a nozzle pipe including slits according to another embodiment of the present invention;

FIG. 3A shows a plan view of a nozzle pipe according to another embodiment of the present invention;

FIG. 3B shows a side cross-sectional view of the nozzle pipe shown in FIG. 3A taken along line IIIB-IIIB;

FIGS. 3C and 3D show a side view of a nozzle pipe including slits according to another embodiment of the present invention;

FIGS. 4 through 11 show various plan views illustrating a slit of a nozzle pipe according to embodiments of the present invention;

FIG. 12A shows thickness uniformity of a thin film deposited using an apparatus for depositing a thin film according to an embodiment of the present invention; and

FIG. 12B shows thickness uniformity of a thin film deposited using an apparatus for depositing a thin film including a nozzle pipe having a circular opening as a control group.

### DETAILED DESCRIPTION OF THE INVENTION

Hereinafter, the present invention will now be described more fully with reference to the accompanying drawings, in which exemplary embodiments of the invention are shown.

The embodiments of the present invention are provided to fully describe the present invention to those of ordinary skill in the art, and the embodiments as described below can be modified in various forms, and as such, the scope of the present invention is not limited to these embodiments.

In addition, in the drawings, the thickness and/or the size of each component may be exaggerated for convenience and clarity, and like reference numerals in the drawings denote like elements. The term “and/or” as used in the present invention includes any and all combinations of one or more associated listed items.

Also, although terms like a first and a second are used to describe various elements, components, regions, layers, and/or portions in various embodiments of the present invention, the elements, components, regions, layers, and/or portions should not be limited by these terms. These terms are only used to distinguish one element, component, region, layer, or portion from another. Therefore, a first element, component, region, layer, or portion discussed below could be termed a second element, component, region, layer, or portion without departing from the teachings of the present invention.

Hereinafter, embodiments of the present invention will now be described with reference to the accompanying drawings which schematically illustrate ideal embodiments of the present invention. In the drawings, the embodiments may be modified in various forms depending on, for example, manufacturing technologies and/or tolerances. Thus, the present invention should not be construed as being limited to the embodiments set forth herein; rather, the present invention includes modifications caused by, for example, the manufacturing process.

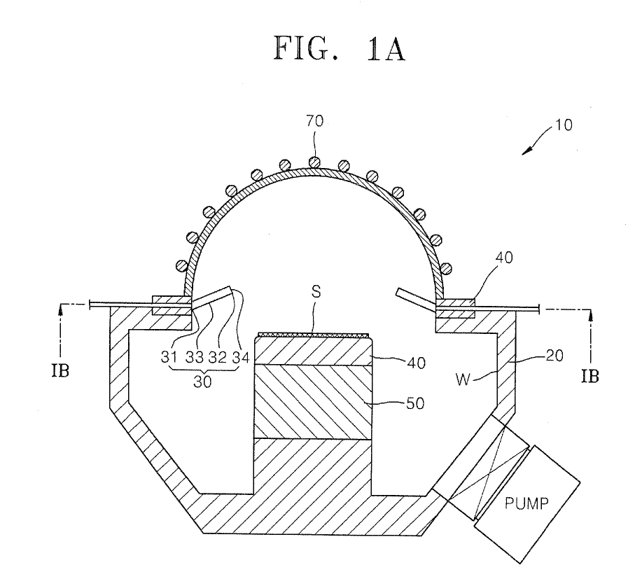

FIG. 1A shows a vertical cross-sectional view of an apparatus for depositing a thin film according to an embodiment of the present invention. FIG. 1B shows a horizontal plan view of the apparatus for depositing a thin film shown in FIG. 1A taken along line IB-IB.

Referring to FIGS. 1A and 1B, an apparatus 10 for depositing a thin film includes a chamber 20 and a nozzle pipe 30 through which process gases are supplied into the chamber 20. According to some embodiments, the apparatus 10 may include a plurality of nozzle pipes 30. An inner-wall W of the chamber 20 defines an inner space in which plasma is formed. A substrate S on which a thin film is deposited is placed on a substrate holder 40.

The substrate holder 40 may include a heating means (not shown) such as a heat coil to heat the substrate for chemical reactions as is well known in the art. To generate plasma in the inner space of the chamber 20, an electrode 50 is disposed on the bottom of the substrate holder 40, and a high-density plasma source, for example, a high frequency coil 70 may be disposed outside of the chamber. The arrangement and types of electrodes and high density plasma source required to generate and sustain plasma are not limited to those described herein. For example, an electrode opposed to the electrode 50 may be disposed in the chamber, and thus an RF power may further be applied. The high-density plasma source may provide helicon plasma, microwave plasma, electron cyclotron resonance plasma, or the like and may include a coil for inductive coupling as illustrated.

The nozzle pipe 30 is fixed in an inner wall W of the chamber 20 and extends into the inner space of the chamber 20. The nozzle pipe 30 includes a first end 31 that is fixed to the chamber inner wall W; a second end 32 toward the inner space of the chamber 20; and a flow path 33 penetrating the nozzle pipe 30 from the first end 31 to the second end 32. The first end 31 of the nozzle pipe 30 is connected to a process gas supply unit (not shown) disposed at an external portion of the chamber 20. During thin film deposition processes, the process gas is supplied through the first end 31 of the nozzle pipe 30 and flows through the flow path 33. The process gas enters the inner space of the chamber 20 through a slit 34 that is disposed at the second end 32 of the nozzle pipe 30 so as to open the flow path 33 to the inner space of the chamber 20.

The nozzle pipe 30 may have various lengths to control uniformity of process gas distribution in the inner space of the chamber 20. In some examples of the present invention, the plurality of nozzle pipes 30 may include a long nozzle pipe 30L having a first length L1 and a short nozzle pipe 30S having a second length L2 shorter than the first length L1. The short nozzle pipe 30S supplies a process gas mainly to edge regions of the substrate, and the long nozzle pipe 30L supplies a process gas mainly to the central region of the substrate S.

In some examples of the present invention, the long nozzle pipe 30L and the short nozzle pipe 30S may be alternatively arranged in a predetermined ratio in consideration of properties of thin film deposition such as flow of the process gas supplied to the inner space of the chamber 20, deposition speed, thickness uniformity and step coverage. For example, one long nozzle pipe 30L per seven short nozzle pipes 30S may be arranged as shown in FIG. 1B. Positions of the first end 31 of the nozzle pipe 30 that is fixed to the chamber inner wall W and angles between each of the nozzle pipes 30 and the substrate S may be adjusted to improve thickness uniformity of the deposited thin film.

In some examples of the present invention, a process gas composed of a single component may be provided through each of the nozzle pipes 30L and 30S. For example, to form an interface insulating layer formed of a silicon oxide, each of SiH4 gas and O2 gas, which are reactant gases, may be supplied to the inner space of the chamber 20 respectively through the nozzle pipes 30L and 30S. In addition, to improve step coverage, a physical etch gas such as Ar and He that can sputter the deposited thin film or a chemical etch gas comprising F and/or Cl, such as CHF3 and CCl4, that can provide volatile reactive by-products may be supplied through other nozzle pipes 30L and 30S along with the reactant gases described above.

In this manner, various gases required to deposit a thin film can be independently supplied through individual nozzle pipes 30L and 30S, and thus properties of thin film deposition such as thickness uniformity, deposition speed and step coverage can be easily controlled. For example, the properties of thin film deposition can be easily adjusted by selectively controlling width, length, and shape of the slit 34 and length of the nozzle pipe 30 of each of the plurality of nozzle pipes 30 using either of the reactant gases and etch gases.

However, the present invention is not limited to supplying a single gas through each of the nozzle pipes 30L and 30S. As required, a mixed gas in a predetermined ratio can be supplied through each of the nozzle pipes 30L and 30S or a reactive species mixed with a carrier gas may also be supplied therethrough.

Hereinafter, various shapes of a slit of a nozzle pipe according to embodiments of the present invention will now be described.

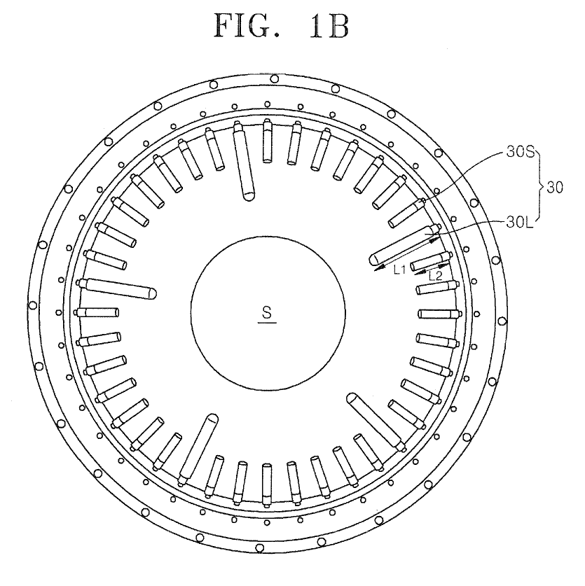

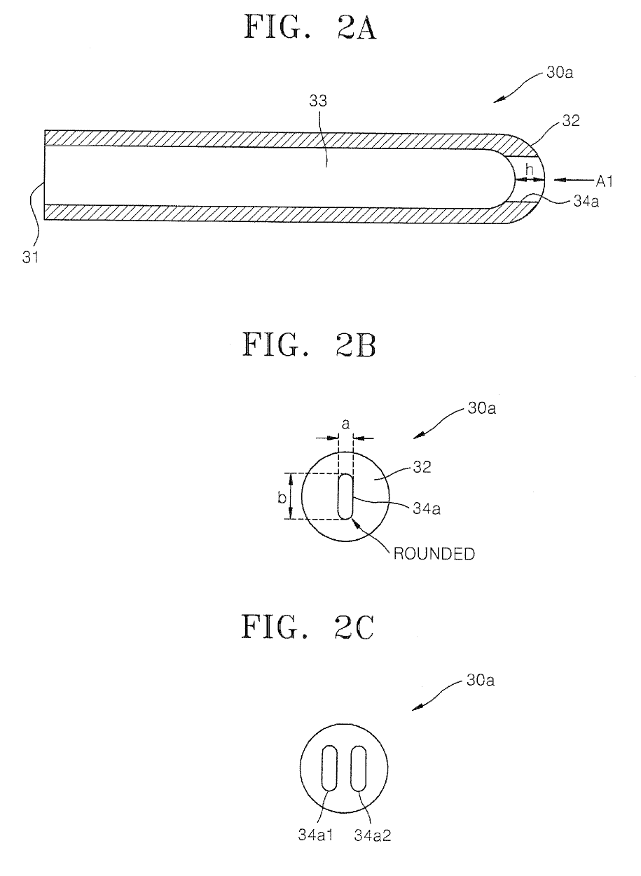

FIG. 2A shows a plan view illustrating a nozzle pipe 30a including a slit 34a according to an embodiment of the present invention. FIG. 2B shows a side view of the nozzle pipe 30a from the direction of an arrow Al shown in FIG. 2. FIG. 2C shows a side view of a nozzle pipe including slits 34a1 and 34a2 according to another embodiment of the present invention. Since the nozzle pipe 30a extends to the inner space of the chamber 20, a second end 32 of the nozzle pipe 30a contacts plasma directly. Particularly, since the long nozzle pipe 30L enters into the plasma volume generated in the chamber 20, an arc discharge may occur.

Accordingly, in some embodiments of the present invention, the second end 32 of the nozzle pipe 30a may be rounded as illustrated in FIG. 2A. Although the rounded second end 32 is charged to have a negative potential, by having a rounded second end 32, field concentration at the second end 32 may be decreased so as to reduce the possibility of an arc discharge which may occur between the second end 32 of the nozzle pipe 30a and the plasma. In another embodiment, only the second end 32 of the long nozzle pipe 30L, having higher possibility of arc discharge than the second end 32 of the short nozzle pipe 30S, may be rounded.

Referring to FIG. 2B, a slit 34a that opens the flow path 33 may be prepared at a terminal end of the second end 32 according to some embodiments of the present invention. The width “a” of the opening of the slit 34a is shorter than the length “b” of the opening of the slit 34a so as to limit the width of the opening. FIG. 2B shows one slit 34a, but the present invention is not limited thereto. A separately disposed pair of slits 34a1 and 34a2 as shown in FIG. 2C may be formed and three or more slits may also be formed.

The inventors of the present invention observed that a larger amount of reactive by-products are deposited on the opening of the nozzle during a thin film deposition process as the width of the opening formed on the nozzle pipe increases. In a circular opening in which the width of the opening is not confined to a certain direction, a large amount of by-products are deposited on the opening of the nozzle pipe. With respect to such phenomenon, the inventors of the present invention concluded that by-products are deposited on the opening of the nozzle pipe by plasma since plasma generated in the inner space of the chamber 20 during the deposition process can be diffused to the opening, and the plasma can be partially sustained in the opening when the width of the opening is sufficiently larger than a sheath width of the plasma.

Accordingly, in order to limit the width of the opening that is exposed to the plasma, various slits 34a, 34a1, and 34a2 are formed at the second end 32 of the nozzle pipe 30a. As a result of experiments, it was observed that deposition of reaction by-products was inhibited at a commonly applied process pressure, e.g., in the range of several mTorr to several Torr, when the width a of the slit is in the range of about 0.5 mm to about 3 mm. The length b of the slit 34a may be determined such that an area of the slit 34a is smaller than or equal to the area of the cross-section of the flow path 33 to provide desirable nozzle properties. When a plurality of slits 34a are formed, the length b of the slits 34a may be determined such that the total area of the slits 34a is smaller than or equal to the area of the cross-section of the flow path 33.

At least one end of the slit 34a may be rounded as illustrated in FIG. 2B. The rounded end of the slit 34a is effective to reduce arc discharge occurrences.

Referring again to FIG. 2A, in some embodiments of the present invention, a depth h of the slit 34a may be in the range of about 1 to about 10 mm. The sufficient depth h of the slit 34a can prevent the plasma from being diffused through the slit 34a to, and sustained in, the flow path 33 having a relatively large width.

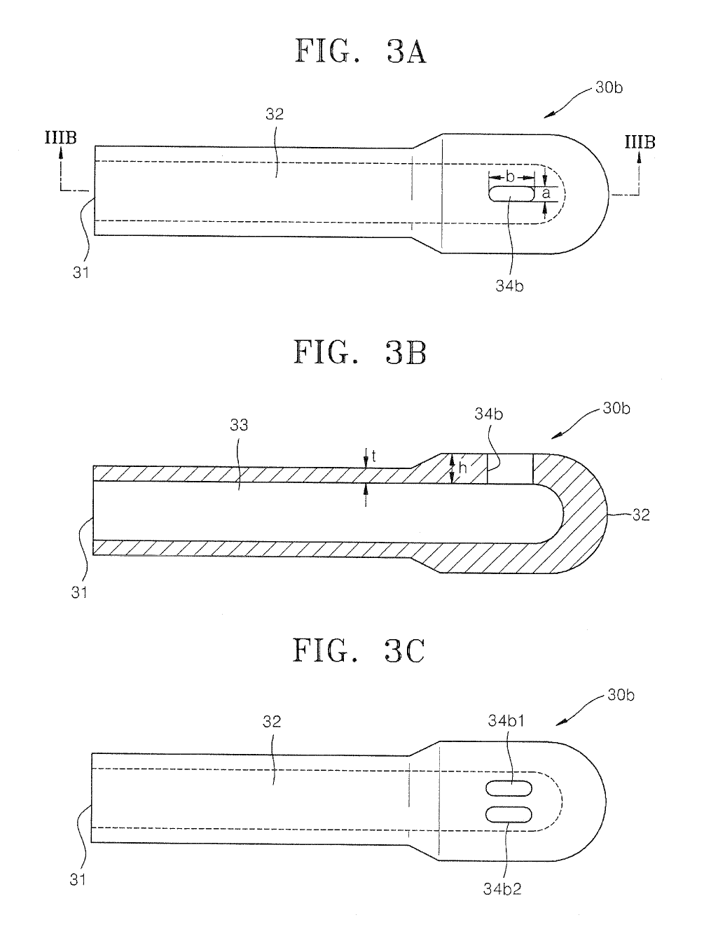

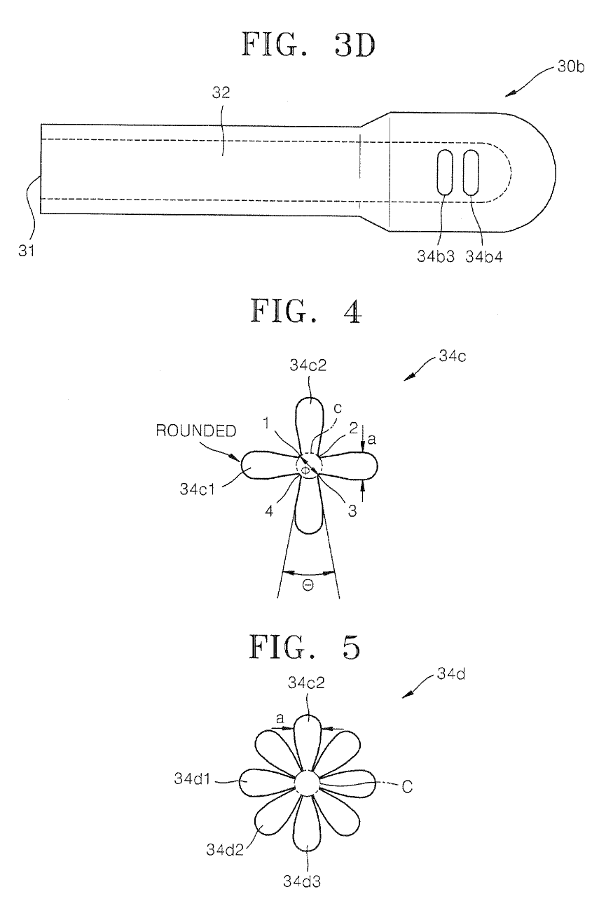

FIG. 3A shows a plan view of a nozzle pipe 30b according to another embodiment of the present invention. FIG. 3B shows a side cross-sectional view of the nozzle pipe 30b shown in FIG. 3A taken along line IIIB-IIIB. FIGS. 3C and 3D show a side view of a nozzle pipe including slits 34b1, 34b2; and 34b3, 34b4, respectively, according to another embodiment of the present invention.

Referring to FIG. 3A, the second end 32 of the nozzle pipe 30b may be rounded as described above with reference to FIG. 2A. In this embodiment, a slit 34b may be formed in a side wall of the second end 32. In another embodiment, a plurality of slits 34b1, 34b2 and 34b3, 34b4 may be formed in a side wall of the second end 32 as shown in FIGS. 3C and 3D.

As illustrated in FIGS. 3A and 3C, the lengthwise direction of the slits 34b, 34b1 and 34b2 may be the same direction to which the flow path 33 extends. When such slits 34b, 34b1 and 34b2 are provided in the long nozzle pipe 30L described with reference to FIGS. 1A and 1B, a virtual plane extending in the lengthwise direction of the slits 34b, 34b1 and 34b2 may be drawn on a diameter line of the substrate S or be parallel to the diameter line of the substrate S to improve thickness uniformity of the thin film deposited on the substrate S.

In another embodiment, the lengthwise direction of the slits 34b3 and 34b4 may form about a 90° angle with a direction to which the flow path 32 extends as illustrated in FIG. 3D. In another embodiment, one of or a combination of at least two slits among various slits 34b, 34b1, 34b2, 34b3 and 34b4 illustrated in FIGS. 3A through 3D may be applied to the nozzle pipe 30b.

The width a of the slit 34b may be in the range of about 0.5 to about 3 mm in order to prevent the plasma from being diffused into the slit 34b or being sustained in the slit 34b at a pressure applied during a thin film deposition process, e.g. in the range of several mTorr to several Torr. The length b of the slit 34b may be determined such that area of the slit 34a is smaller than or equal to the area of the cross-section of the flow path 33 so as to exhibit desirable nozzle properties. When a plurality of slits 34b1, 34b2 and/or 34b3, 34b4 are formed in the nozzle pipe 30b as shown in FIGS. 3C and 3D, the length b of the slits 34b1, 34b2, 34b3 and 34b4 may be determined such that the total area of the openings defined by the slits 34b1, 34b2, 34b3 and 34b4 is smaller than or equal to the area of the cross-section of the flow path 33. Further, in some embodiments, at least one end of the slit 34b may be rounded as shown in FIGS. 3A through 3D.

Referring to FIG. 3B, a depth h of the slit 34b may be in the range of about 1 to about 10 mm. In some embodiments, the thickness of a side wall of the second end 32 in which the slit 34b is disposed may be larger than the thickness t of the side wall at the flow path 33 to obtain a sufficient depth h of the slit 34b. As a result, the second end 32 of the nozzle pipe 30b may be protruded compared to the outer wall of the flow path 33.

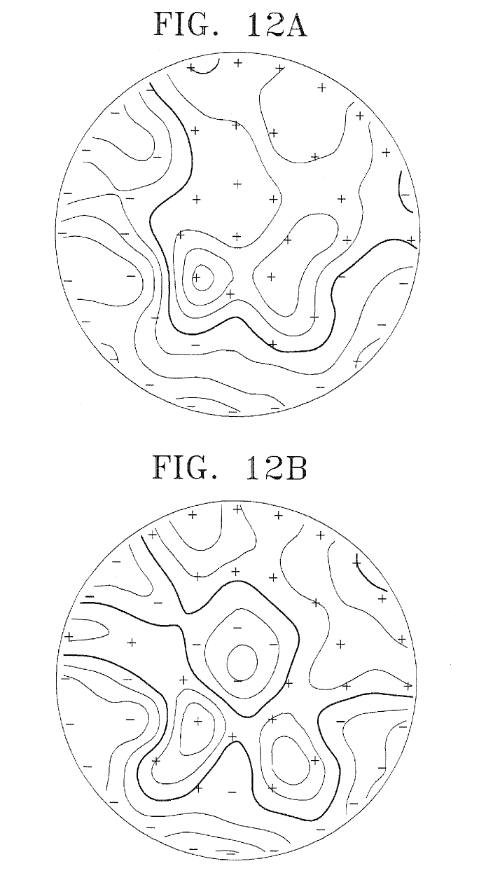

The depth h of the slits 34a and 34b may improve directionality of the reactant gases emitted from the slits 34a and 34b as well as prevent the plasma from being diffused into the flow path 33 through the slits 34a and 34b and, therefore, being sustained in the flow path 33 as described above. When the slits 34a and 34b are applied to the side wall of the second end 32 of the long nozzle pipe 30L shown in FIG. 1B, the amount of reactant gases flowing to the central region of the substrate S may increase due to the straight path of the reactant gases. Accordingly, a reasonable level of the deposition rate can be obtained at the central region of the substrate S, and thus thickness uniformity of the deposited thin film can be improved. The results will be described below with reference to FIGS. 12A and 12B.

Hereinafter, shapes of slits according to embodiments of the present invention will now be described. The slits may be applied to a terminal or a side wall of the second end 32 of the nozzle pipe 30 as described above with reference to FIGS. 2A through 3D.

FIGS. 4 through 11 show various plan views illustrating slits 34c, 34d, 34e, 34f, 34g, 34h, 34i, and 34j of a nozzle pipe 30 according to embodiments of the present invention. The following properties about width a, depth h, (rounded) shape of a terminal, angle of inclination θ, and arranging manner of the slits 34c, 34d, 34e, 34f, 34g, 34h, 34i, and 34j can be applied to other embodiments without further description thereof.

Referring to FIG. 4, in the slit 34c, a first slit 34c1 and a second slit 34c2 may cross each other at their centers. When the first slit 34c1 crosses the second slit 34c2 at right angles as illustrated, a cross type opening may be formed at the second end 32 of the nozzle pipe 30. The width a of the first slit 34c1 and the second slit 34c2 may be in the range of about 0.5 mm to about 3 mm. In some embodiments, the lengthwise direction of the first slit 34c1 may be arranged to be parallel to the direction to which the flow path 33 extends.

A diameter Φ of a virtual circle defined by intersections 1, 2, 3 and 4 of the first slit 34c1 and the second slit 34c2 may be in the range of about 0.5 mm to about 3 mm to prevent the plasma from being diffused and sustained in the flow path 33, similar to the width a of the slits 34a34c1 and 34b described above. Each of the intersections 1, 2, 3 and 4 is rounded by grinding or cutting in order to lessen field concentration which may occur at the intersections 1, 2, 3 and 4.

The width a of the first slit 34c1 and the second slit 34c2 may increase away from the center. Accordingly, the first slit 34c1 and the second slit 34c2 may have an angle of inclination θ in the range of about 5° to about 45°.

During the actual rounding process, the diameter Φ of the virtual circle defined by the intersections 1, 2, 3 and 4 of the first slit 34c1 and the second slit 34c2 may be larger than that desired due to manufacturing tolerances of the rounding process. In this case, the slit 34c1 and 34c2 may not be able to limit the diffusion and/or sustainment of the plasma. Reduction in the width a of the first slit 34c1 and the second slit 34c2 at the center may result in a virtual circle C having the desired diameter Φ despite the manufacturing tolerances of the rounding process. Further, the area of external regions of the virtual circle C may become relatively larger than the area of the virtual circle C by increasing the width a of the first slit 34c1 and the second slit 34c2 away from the center.

As shown in FIG. 5, two second slits 34d2 and 34d3 may cross the first slit 34d1 at the center, and accordingly, the slit 34d may have a shape similar to flower petals. At least one end of the slits 34d1, 34d2 and 34d3 may be rounded as shown in FIG. 4.

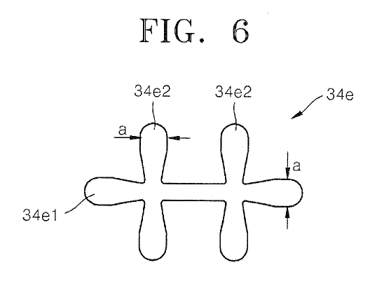

Referring to FIGS. 6 and 7, the slits 34e and 34f may have shapes in which two or three separate second slits 34e2, 34f2 respectively cross the first slit 34e1, 34f1 arranged in the same direction to which the flow path 33 extends. As illustrated, the first slit 34e1, 34f1 and the second slits 34e2, 34f2 may cross at right angles. The second slits 34e2, 34f2 may cross the first slit 34e1, 34f1 at both terminal portions and/or a center portion.

The width a of the slits 34e1, 34e2; 34f1 and 34f2 may be in the range of about 0.5 mm to about 3 mm. The diameter of virtual circles defined by intersections of the first slit 34e1, 341 and the second slits 34e2, 34f2 may be limited to the range of about 0.5 mm to about 3 mm to prevent plasma from being diffused and sustained in the flow path 33, similar to the width a of the slits34c1, 34c2, as described with reference to FIG. 4. The intersections may be rounded to prevent are discharge as described above.

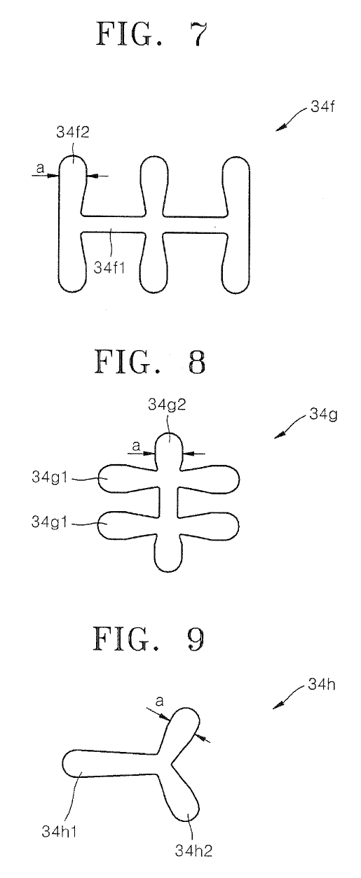

Referring to FIG. 8, the slit 34g may have a configuration in which the second slit 34g2 may cross two first slits 34g1 which do not cross each other. As illustrated, the first slits 34g1 may cross the second slit 34g2 at right angles.

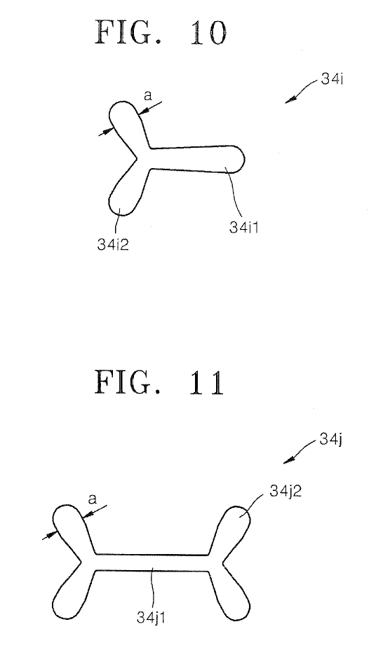

Referring to FIGS. 9 through 11, the slits 34h, 34i, and 34j may have configurations in which the first slits 34h1 , 34i1, and 34j1 may cross the second slits 34h2, 34i2, and 34j2 at one end or both ends of the first slits 34h1, 34i1, and 34j1 at a predetermined angle. Some embodiments may have the same crossing angles.

Those of ordinary skill in the art would appreciate with reference to FIGS. 4 through 11 that the slits 34c, 34d, 34e, 34f, 34g, 34h, 34i, and 34j according to embodiments of the present invention may have any one of the properties illustrated or a combination of properties illustrated among the width a, depth h, (rounded) shape of a terminal, angle of inclination θ, and manner of arranging the slits. Dimensions for the slit according to various embodiments of the present invention may be properly selected to prevent plasma from being diffused through the slit or sustained in the slit during the process of depositing a thin film. Further, the total area of the opening of the slits may be determined so as to be smaller than or equal to the area of the cross-section of the flow path to provide nozzle pipe properties.

Further, thickness uniformity of the deposited thin film can be effectively controlled by improving directionality of reactant gases supplied into the inner space of the chamber with a proper depth of the slit, e.g., in the range of about 1 to about 10 mm, as well as an appropriate shape of the slits of the nozzle pipe.

Hereinafter, the effects of a nozzle pipe including a slit according to embodiments of the present invention on preventing by-products from being deposited and improving thickness uniformity of a thin film will be described. A nozzle pipe including a slit according to embodiments of the present invention and a nozzle pipe including a circular opening as a control group were prepared, and deposition properties thereof were compared to each other. A silicon oxide thin film was formed at a chamber pressure of 3 mTorr using SiH4 gas and O2 gas as reactants gases, and Ar as an etch gas.

In both of the present invention and the control group, a combination of 6 long nozzle pipes and 30 short nozzle pipes was used. SiH4 gas was supplied through the 6 long nozzle pipes, O2 gas was supplied through 12 short nozzle pipes, and Ar gas was supplied through 18 short nozzle pipes.

A cross type slit, as shown in FIG. 4, was applied to a side wall of the long nozzle pipe according to the present invention. A circular opening was applied to a side wall of the long nozzle pipe according to the control group. A slit was formed in the terminal of the second end of the short nozzle pipe according to the present invention, and a circular opening was formed in the terminal of the second end of the short nozzle pipe of the control group. The maximum width of the slit was 3 mm and the maximum depth of the slit was 3 mm. The circular opening of the control group had a diameter of 8 mm and a depth of 1.44 mm.

In order to ensure that the inclusion of the slit was the only process parameter that was varied, the cross-section of all of the flow paths of the nozzle pipes in both of the present invention and the control group were a circle and the inner diameter was 8 mm. The length and arranging manner of the long nozzle pipes and the short nozzle pipes were the same in both groups. Further, the speed of reactant gases flowing into the chamber was the same in both groups to reconcile the area of an opening by the slit with the area of a circular opening.

Table 1 shows cleaning time and productivity of an apparatus for depositing a thin film including a nozzle pipe according to an embodiment of the present invention and a nozzle pipe of the control group.

TABLE 1

| | | Slit (example of the | Circular opening | |
|---|---|---|---|---|
| Items | | present invention) | (control group) | Effects |
| Cleaning | Cleaning time | 557 seconds | 741 seconds | Reduction by 25% |
| | Number of | 400 | 250 | Reduction by 40% |
| | particles | | | |
| Productivity | UPH | 35.9 wafers | 45 wafers | Increase by 25% |
| | PM cycle | 10,000 wafers | 20,000 wafers | Increase by 100% |

Referring to Table 1, the cleaning time and the number of particles observed by the naked eye at the second end of the nozzle pipe using the slit were reduced by 25% and 40%, respectively, compared to those using the circular opening. That is, deposition of by-products generated during the thin film deposition process can be effectively reduced by applying a nozzle pipe including the slit to the cleaning process. According to the embodiment of the present invention, productivity (units per hour (UPH)) increased by 25%, and the preventive maintenance (PM) cycle increased by 100% according to the embodiment of the present invention. As a result, productivity of the deposition process for semiconductor thin film depositions was improved.

FIG. 12A shows thickness uniformity of a thin film deposited using an apparatus for depositing a thin film according to an embodiment of the present invention, and FIG. 12B shows thickness uniformity of a thin film deposited using an apparatus for depositing a thin film including a nozzle pipe having a circular opening as a control group. The thickness at 49 points of the deposited thin film was measured using an optical method, and the results were mapped using an interpolation method. In FIGS. 12A and 12B, regions having the same thickness are shown by a line to illustrate the thickness distribution using a contour line. The regions shown as “+” indicate portions thicker than the mean thickness, and the regions shown as “−” indicate portions thinner than the mean thickness.

Referring to FIG. 12A, the thin film on the central region of the substrate had sufficient thickness using a nozzle pipe according to the embodiment of the present invention (shown as “+”). On the contrary, referring to FIG. 12B, the thin film on the central region of the substrate had insufficient thickness using a nozzle having a circular opening (shown as Since the thickness of the thin film at the central region of the substrate is mainly controlled by the long nozzle pipe, a sufficient deposition speed can be obtained at the central region of the substrate using the nozzle pipe having the slit according to the embodiment of the present invention compared to the circular opening as is the case in the control group. When process parameters of the short nozzle pipe are varied, deposition properties of edge regions of the substrate can be controlled, and thus more uniform thickness of the thin film can be obtained.

As described herein, directionality of the process gas flow which is supplied into the inner space of the chamber through the slit can be improved using the nozzle pipe having the slit according to the present invention. In addition, the process gas flow can have various properties according to the directions and arrangement of the slits according to the embodiment of the present invention compared to the circular opening, and thus deposition speed at the central region of the substrate can be raised and thickness uniformity of the deposited thin film can also be improved.

The apparatus for depositing a thin film using plasma can be applied to form an insulating interlayer for semiconductor devices, a device isolation layer such as shallow trench isolation (STI), and a passivation layer by selecting a proper gas. To achieve these functions, for example, one of an oxide layer, a nitride layer, an oxygen nitride layer, and a combination thereof may be deposited. However, the apparatus for depositing a thin film according to the present invention is not limited thereto.

The reactant gas to form a thin film in the apparatus for depositing a thin film is supplied into the chamber through the flow path of the nozzle pipe. In some embodiments, the nozzle pipe may be formed of an insulator, for example, an aluminum nitride or an aluminum oxide. Particularly, since the aluminum nitride has excellent abrasion resistance, impurities generated from plasma damage can be reduced using a nozzle pipe formed of aluminum nitride.

The apparatus for depositing a thin film of the present invention includes a nozzle pipe having a slit which controls diffusion and sustainment of plasma, and thus reaction products or impurities can be prevented from being deposited on the nozzle pipe, and manufacturing costs can be reduced by extending cleaning and exchanging cycles of nozzles.

In addition, according to the method of depositing a thin film according to the present invention, process gases including reactant gases are supplied through the slit which controls diffusion and sustainment of plasma, and thus reaction products and impurities can be inhibited from being deposited on the nozzle pipe, and manufacturing costs can be reduced by extending cleaning and exchanging cycles of nozzles. Further, thickness uniformity of the deposited thin film can be controlled by controlling shapes of the slit, and thus a thin film having uniform thickness can be easily deposited.

According to an aspect of the present invention, there is provided an apparatus for depositing a thin film using plasma including a chamber having a substrate holder and an inner space defined by an inner wall; and a nozzle pipe including a first end fixed to the inner wall of the chamber; a second end extending into the inner space of the chamber; a flow path penetrating the nozzle pipe from the first end to the second end; and at least one slit which is disposed at the second end and opens the flow path.

The first slit may have a width in the range of about 0.5 mm to about 3 mm. Further, at least one end of the first slit may be rounded. Also, the first slit may have a depth in the range of about 1 mm to about 10 mm. A side wall of the second end may be thicker than a wall of the flow path to secure a sufficient depth of the slit. The slit may be formed in a side wall of the second end. The lengthwise direction of the slit may be parallel to a direction in which the flow path extends. An area of an opening of the slit may be smaller than or equal to an area of the cross-section of the flow path. A process gas that is used to form an insulating interlayer, a device separation layer and a passivation layer may be supplied through the flow path. The nozzle pipe may be formed of an insulator. The nozzle pipe insulator may comprise aluminum nitride and/or aluminum oxide. The apparatus may further comprise a high-density plasma source.

According to some embodiments, the nozzle pipe comprises a plurality of nozzle pipes including a long nozzle pipe having a first length and a short nozzle pipe having a second length which is smaller than the first length. The long nozzle pipe and the short nozzle pipe may be alternatively arranged in a predetermined ratio. The slit may be disposed only in the long nozzle pipe. Also, the slit may be directed toward the center of the substrate.

According to another aspect of the present invention, there is provided an apparatus for depositing a thin film using plasma including a chamber having inner space defined by a substrate holder and an inner wall; and a chamber having a substrate holder and an inner space defined by an inner wall; and a nozzle pipe including a first end fixed to the inner-wall of the chamber; a second end toward inner space of the chamber; a flow path penetrating the nozzle pipe from the first end to the second end; at least one first slit and at least one second slit which crosses the first slit, wherein the first slit and second slit are disposed at the second end and open the flow path into the inner space of the chamber.

The first slit and the second slit may have a width in the range of about 0.5 mm to about 3 mm. Further, a diameter of a virtual circle defined by the first slit and the second slit may be in the range of about 0.5 mm to about 3 mm. The intersections may be rounded to alleviate field concentration due to plasma.

The first slit may cross the second slit at their center. When the first slit crosses the second slit at right angles, a cross type slit is formed. The width of the first slit and the second slit may increase away from the center of the first slit and the first slit.

The first slit and the second slit may be formed in a side wall of the second end of the nozzle pipe. Here, the side wall of the second end may be thicker than the wall of the flow path to have a sufficient depth of the first slit and the second slit.

According to still another aspect of the present invention, a method of depositing a thin film using plasma comprises: providing a chamber having a substrate and an inner space defined by an inner wall of the chamber; mounting a substrate on which a thin film is to be deposited on the substrate holder; and providing a process gas into the inner space of the chamber using a plurality of nozzle pipes, wherein at least one of the plurality of nozzle pipes comprises a slit.

Each of the plurality of nozzle pipes may comprise a first end fixed to an inner wall of the chamber; a second end extending into the inner space of the chamber; and a flow path penetrating the nozzle pipe from the first end to the second end, wherein the slit is disposed at the second end and opens the flow path into the inner space of the chamber. The slit may be formed in a side wall of the second end. The lengthwise direction of the slit may be parallel to a direction to which the flow path extends. The plurality of nozzle pipes may comprise a long nozzle pipe having a first length and a short nozzle pipe having a second length which is smaller than the first length. The slit may be formed only in the long nozzle pipe. The slit may comprise a first slit and at least one second slit crossing the first slit. A width of the slit may be in the range of about 0.5 mm to about 3 mm. Each of the nozzle pipes may provide a process gas having a single component.

According to some embodiments, the thin film to be deposited is selected from the group consisting of an insulating interlayer, a device separation layer and a passivation layer. More specifically, the thin film to be deposited may be one layer selected from the group consisting of an oxide layer, a nitride layer, an oxygen nitride layer and a combination of theses layers.

According to the method, a plasma may be generated in the chamber and the plasma may be a high-density plasma. The process gas may comprise reactant gases which chemically react with each other on the substrate and etch gases which etch the thin film.

According to some embodiments of the present invention plasma generated during a thin film deposition process is inhibited from being diffused into the slit and the diffused plasma is inhibited from being sustained in the slit, by forming the slit at the second end of the nozzle pipe as a member capable of controlling a width of an opening of the nozzle pipe exposed to plasma. According to some embodiments of the present invention, deposition of by-products and/or impurities at the second end of the nozzle pipe at a commonly applied process pressure, for example, in the range of several mTorr to several Torr, can be minimized by controlling the width of the slit.

Since the thin film thickness at the central region of a substrate is mainly determined by a long nozzle pipe during a thin film deposition, deposition speed at the central region of the substrate can be improved by improving directionality of reactant gases according to some embodiments of the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for depositing a thin film using plasma comprising:
a chamber having a substrate holder and an inner space defined by an inner wall; and
a nozzle pipe comprising:
a first end fixed to the inner-wall of the chamber;
a second end extending into the inner space of the chamber;
a flow path penetrating the nozzle pipe from the first end to the second end; and
at least one slit which is disposed at the second end and opens the flow path.

2. The apparatus of claim 1, wherein the nozzle pipe comprises a plurality of nozzle pipes including a long nozzle pipe having a first length and a short nozzle pipe having a second length which is smaller than the first length.

3. The apparatus of claim 1, wherein the slits of the plurality of nozzle pipes open the flow paths into the inner space.

4. The apparatus of claim 1, wherein the second end of the nozzle pipe is rounded.

5. The apparatus of claim 1, wherein at least one end of the slit is rounded.

6. The apparatus of claim 1, wherein a side wall of the second end is thicker than a wall of the flow path to secure a sufficient depth of the slit.

7. The apparatus of claim 1, wherein the slit is disposed in a side wall of the second end.

8. The apparatus of claim 1, wherein the lengthwise direction of the slit is parallel to a direction in which the flow path extends.

9. The apparatus of claim 1, wherein the area of an opening of the slit is smaller than or equal to the area of the cross-section of the flow path.

10. The apparatus of claim 1, wherein the nozzle pipe comprises one or more of aluminum nitride and aluminum oxide.

11. An apparatus for depositing a thin film using plasma comprising:
a chamber having a substrate holder and an inner space defined by an inner wall; and
a nozzle pipe comprising:
a first end fixed to the inner wall of the chamber;
a second end extending into the inner space of the chamber;
a flow path penetrating the nozzle pipe from the first end to the second end; and
at least one first slit and at least one second slit which crosses the first slit, wherein the first slit and second slit are disposed at the second end and open the flow path.

12. The apparatus of claim 11, wherein intersections of the first slit and the second slit are rounded and wherein the first slit and the second slit open the flow path into the inner space of the chamber.

13. The apparatus of claim 11, wherein a width of the first slit and a width of the second slit increase away from the center of the first slit and the second slit.

14. The apparatus of claim 11, wherein at least one end of the first slit and/or the second slit is rounded.

15. The apparatus of claim 11, wherein the first slit and the second slit are disposed in a side wall of the second end.

16. The apparatus of claim 11, wherein the lengthwise direction of the first slit is parallel to a direction in which the flow path extends.

17. The apparatus of claim 11, wherein the area of an opening of the first slit and the second slit is smaller than or equal to the area of the cross-section of the flow path.

18. The apparatus of claim 11, wherein the nozzle pipe comprises a plurality of nozzle pipes including a long nozzle pipe having a first length and a short nozzle pipe having a second length which is smaller than the first length.

19. The apparatus of claim 11, wherein the second end of the nozzle pipe is rounded.

20. A method of depositing a thin film using plasma, the method comprising:
preparing a chamber having a substrate holder and an inner space defined by an inner-wall;
mounting a substrate, on which a thin film is to be deposited, on the substrate holder; and
providing a process gas into the inner space of the chamber using a plurality of nozzle pipes comprising a slit.
